(19) United States
(12) Patent Application Publication
(10) Pub. No.: US 2018/0081546 A1
(43) Pub. Date: Mar. 22, 2018

(54) MODIFYING INFORMATION DISPERSAL ALGORITHM (IDA) THRESHOLDS BY SPLITTING EXISTING SLICES

(71) Applicant: International Business Machines Corporation, Armonk, NY (US)

(72) Inventors: Wesley B. Leggette, Chicago, IL (US); Andrew D. Baptist, Mt. Pleasant, WI (US); Greg R. Dhuse, Chicago, IL (US); Jason K. Resch, Chicago, IL (US); Gary W. Grube, Barrington Hills, IL (US); S. Christopher Gladwin, Chicago, IL (US)

(21) Appl. No.: 15/823,865

(22) Filed: Nov. 28, 2017

Related U.S. Application Data
(63) Continuation-in-part of application No. 14/102,987, filed on Dec. 11, 2013.
(60) Provisional application No. 61/760,962, filed on Feb. 5, 2013.

(51) Int. Cl. G06F 3/06; H04L 29/08; G06F 11/10

(52) U.S. Cl. CPC G06F 3/064; H04L 67/1097; H03M 13/1515; G06F 3/067; G06F 11/1076

(57) ABSTRACT

A storage unit (SU) includes an interface configured to interface and communicate with a dispersed storage network (DSN), a memory that stores operational instructions, and processing circuitry operably coupled to the interface and to the memory. The SU stores a slice associated with a data object. The SU splits the slice into at least two new slices in accordance with second dispersed error encoding parameters. The SU then transmits a first new slice to a first other SU and a second new slice to a second other SU of a second SU set to be stored therein. The SU generates a first combined partial slice associated with a third new slice of the plurality of new slices to be stored in a third other SU of the second SU set and transmits it to the third other SU to be used to generate the third new slice.

### CROSS REFERENCE TO RELATED PATENTS

The present U.S. Utility patent application also claims priority pursuant to 35 U.S.C. § 120, as a continuation-in-part (CIP) of U.S. Utility patent application Ser. No. 14/102,987, entitled “UPDATING SHARED GROUP INFORMATION IN A DISPERSED STORAGE NETWORK,” filed Dec. 11, 2013, pending, which claims priority pursuant to 35 U.S.C. § 119(e) to U.S. Provisional Application No. 61/760,962, entitled “MANAGING A DISPERSED STORAGE NETWORK POWER CONSUMPTION,” filed Feb. 5, 2013, both of which are hereby incorporated herein by reference in their entirety and made part of the present U.S. Utility patent application for all purposes.

### STATEMENT REGARDING FEDERALLY SPONSORED RESEARCH OR DEVELOPMENT

Not applicable.

### INCORPORATION-BY-REFERENCE OF MATERIAL SUBMITTED ON A COMPACT DISC

Not applicable.

### BACKGROUND OF THE INVENTION

### Technical Field of the Invention

This invention relates generally to computer networks and more particularly to dispersing error encoded data.

### Description of Related Art

Computing devices are known to communicate data, process data, and/or store data. Such computing devices range from wireless smart phones, laptops, tablets, personal computers (PC), work stations, and video game devices, to data centers that support millions of web searches, stock trades, or on-line purchases every day. In general, a computing device includes a central processing unit (CPU), a memory system, user input/output interfaces, peripheral device interfaces, and an interconnecting bus structure.

As is further known, a computer may effectively extend its CPU by using “cloud computing” to perform one or more computing functions (e.g., a service, an application, an algorithm, an arithmetic logic function, etc.) on behalf of the computer. Further, for large services, applications, and/or functions, cloud computing may be performed by multiple cloud computing resources in a distributed manner to improve the response time for completion of the service, application, and/or function. For example, Hadoop is an open source software framework that supports distributed applications enabling application execution by thousands of computers.

In addition to cloud computing, a computer may use “cloud storage” as part of its memory system. As is known, cloud storage enables a user, via its computer, to store files, applications, etc. on an Internet storage system. The Internet storage system may include a RAID (redundant array of independent disks) system and/or a dispersed storage system that uses an error correction scheme to encode data for storage.

Prior art data storage systems can operate very inefficiently when restoring, replicating, and/or regenerating data. For example, the throughput requirements of a communication system may be pushed to the limit and possible adversely affect other communications and operations within the communication system. There exists a need for improvement of the manner by which data storage systems operate including for operations related to restoring, replicating, and/or regenerating data.

### BRIEF DESCRIPTION OF THE SEVERAL VIEWS OF THE DRAWING(S)

FIG. 1 is a schematic block diagram of an embodiment of a dispersed or distributed storage network (DSN) in accordance with the present invention;

FIG. 2 is a schematic block diagram of an embodiment of a computing core in accordance with the present invention;

FIG. 3 is a schematic block diagram of an example of dispersed storage error encoding of data in accordance with the present invention;

FIG. 4 is a schematic block diagram of a generic example of an error encoding function in accordance with the present invention;

FIG. 5 is a schematic block diagram of a specific example of an error encoding function in accordance with the present invention;

FIG. 6 is a schematic block diagram of an example of a slice name of an encoded data slice (EDS) in accordance with the present invention;

FIG. 7 is a schematic block diagram of an example of dispersed storage error decoding of data in accordance with the present invention;

FIG. 8 is a schematic block diagram of a generic example of an error decoding function in accordance with the present invention;

FIG. 9 is a schematic block diagram of another embodiment of a distributed computing system in accordance with the present invention;

FIG. 10 is a flowchart illustrating an example of re-storing data utilizing different data storage parameters in accordance with the present invention; and

FIG. 11 is a diagram illustrating an embodiment of a method for execution by one or more computing devices and/or storage units (SUs) in accordance with the present invention.

### DETAILED DESCRIPTION OF THE INVENTION

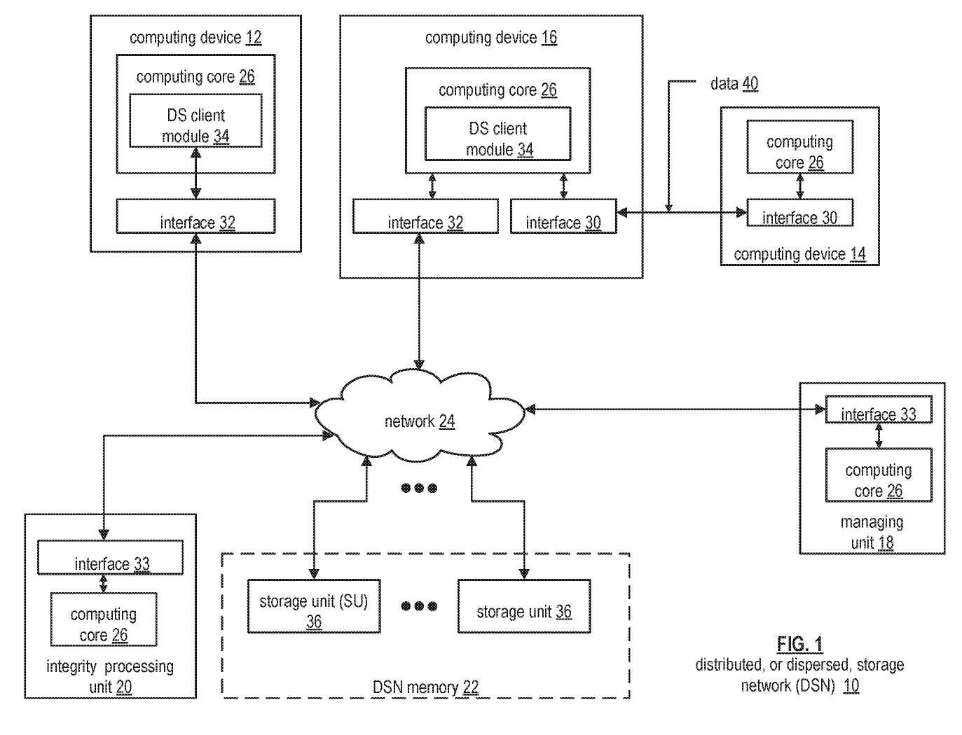

FIG. 1 is a schematic block diagram of an embodiment of a dispersed, or distributed, storage network (DSN) 10 that includes a plurality of computing devices 12-16, a managing unit 18, an integrity processing unit 20, and a DSN memory 22. The components of the DSN 10 are coupled to a network 24, which may include one or more wireless and/or wire lined communication systems; one or more non-public intranet systems and/or public internet systems; and/or one or more local area networks (LAN) and/or wide area networks (WAN).

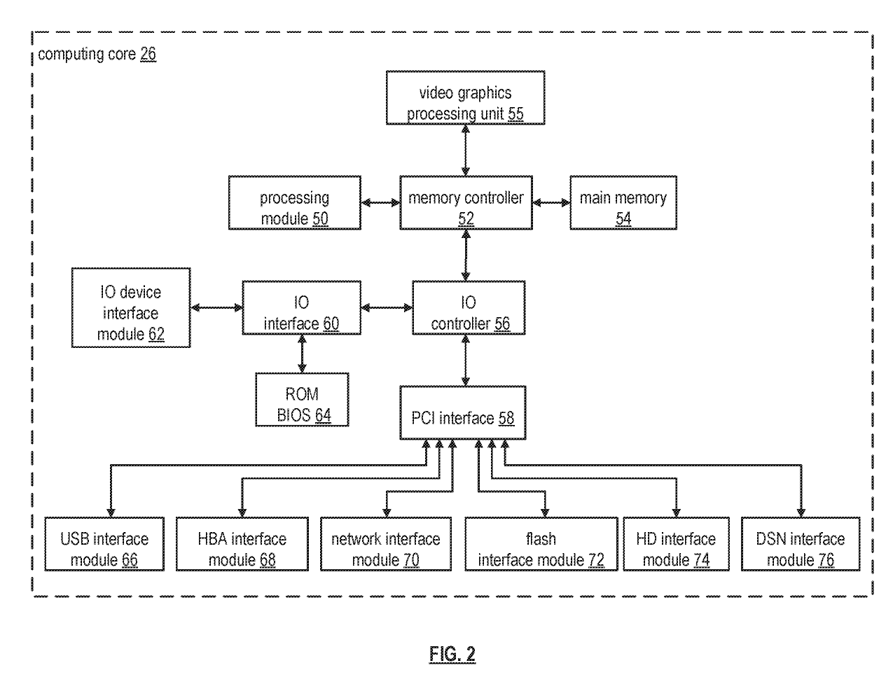

The DSN memory 22 includes a plurality of storage units 36 that may be located at geographically different sites (e.g., one in Chicago, one in Milwaukee, etc.), at a common site, or a combination thereof. For example, if the DSN memory 22 includes eight storage units 36, each storage unit is located at a different site. As another example, if the DSN memory 22 includes eight storage units 36, all eight storage units are located at the same site. As yet another example, if the DSN memory 22 includes eight storage units 36, a first pair of storage units are at a first common site, a second pair of storage units are at a second common site, a third pair of storage units are at a third common site, and a fourth pair of storage units are at a fourth common site. Note that a DSN memory 22 may include more or less than eight storage units 36. Further note that each storage unit 36 includes a computing core (as shown in FIG. 2, or components thereof) and a plurality of memory devices for storing dispersed error encoded data.

Each of the computing devices 12-16, the managing unit 18, and the integrity processing unit 20 include a computing core 26, which includes network interfaces 30-33. Computing devices 12-16 may each be a portable computing device and/or a fixed computing device. A portable computing device may be a social networking device, a gaming device, a cell phone, a smart phone, a digital assistant, a digital music player, a digital video player, a laptop computer, a handheld computer, a tablet, a video game controller, and/or any other portable device that includes a computing core. A fixed computing device may be a computer (PC), a computer server, a cable set-top box, a satellite receiver, a television set, a printer, a fax machine, home entertainment equipment, a video game console, and/or any type of home or office computing equipment. Note that each of the managing unit 18 and the integrity processing unit 20 may be separate computing devices, may be a common computing device, and/or may be integrated into one or more of the computing devices 12-16 and/or into one or more of the storage units 36.

Each interface 30, 32, and 33 includes software and hardware to support one or more communication links via the network 24 indirectly and/or directly. For example, interface 30 supports a communication link (e.g., wired, wireless, direct, via a LAN, via the network 24, etc.) between computing devices 14 and 16. As another example, interface 32 supports communication links (e.g., a wired connection, a wireless connection, a LAN connection, and/or any other type of connection to/from the network 24) between computing devices 12 & 16 and the DSN memory 22. As yet another example, interface 33 supports a communication link for each of the managing unit 18 and the integrity processing unit 20 to the network 24.

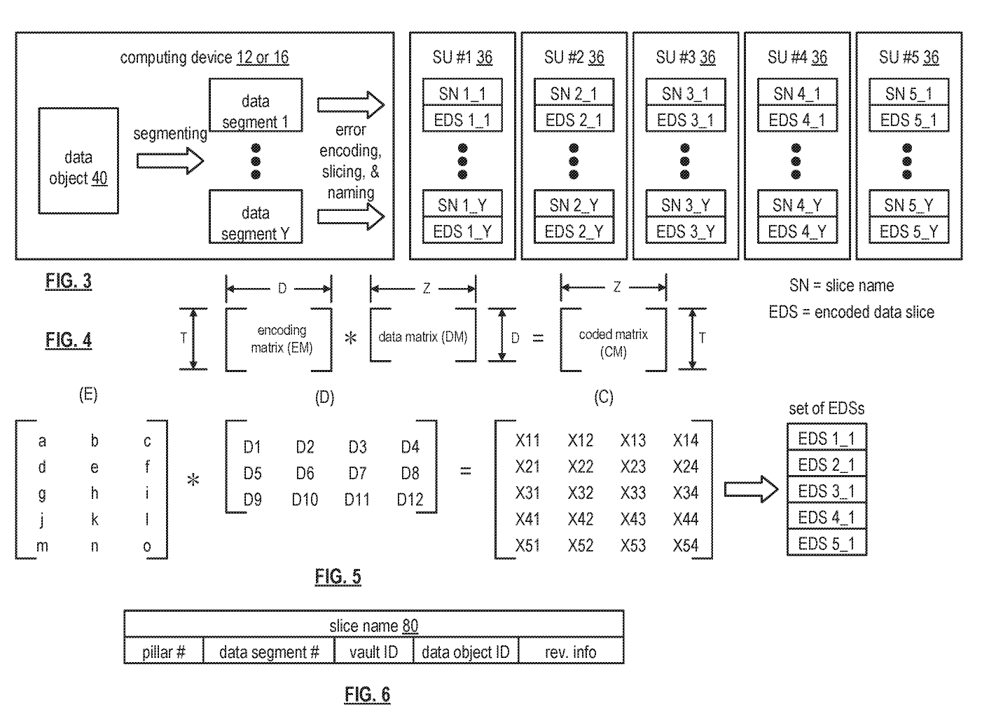

Computing devices 12 and 16 include a dispersed storage (DS) client module 34, which enables the computing device to dispersed storage error encode and decode data as subsequently described with reference to one or more of FIGS. 3-8. In this example embodiment, computing device 16 functions as a dispersed storage processing agent for computing device 14. In this role, computing device 16 dispersed storage error encodes and decodes data on behalf of computing device 14. With the use of dispersed storage error encoding and decoding, the DSN 10 is tolerant of a significant number of storage unit failures (the number of failures is based on parameters of the dispersed storage error encoding function) without loss of data and without the need for a redundant or backup copies of the data. Further, the DSN 10 stores data for an indefinite period of time without data loss and in a secure manner (e.g., the system is very resistant to unauthorized attempts at accessing the data).

In operation, the managing unit 18 performs DS management services. For example, the managing unit 18 establishes distributed data storage parameters (e.g., vault creation, distributed storage parameters, security parameters, billing information, user profile information, etc.) for computing devices 12-14 individually or as part of a group of user devices. As a specific example, the managing unit 18 coordinates creation of a vault (e.g., a virtual memory block associated with a portion of an overall namespace of the DSN) within the DSN memory 22 for a user device, a group of devices, or for public access and establishes per vault dispersed storage (DS) error encoding parameters for a vault. The managing unit 18 facilitates storage of DS error encoding parameters for each vault by updating registry information of the DSN 10, where the registry information may be stored in the DSN memory 22, a computing device 12-16, the managing unit 18, and/or the integrity processing unit 20.

The DSN managing unit 18 creates and stores user profile information (e.g., an access control list (ACL)) in local memory and/or within memory of the DSN module 22. The user profile information includes authentication information, permissions, and/or the security parameters. The security parameters may include encryption/decryption scheme, one or more encryption keys, key generation scheme, and/or data encoding/decoding scheme.

The DSN managing unit 18 creates billing information for a particular user, a user group, a vault access, public vault access, etc. For instance, the DSN managing unit 18 tracks the number of times a user accesses a non-public vault and/or public vaults, which can be used to generate a per-access billing information. In another instance, the DSN managing unit 18 tracks the amount of data stored and/or retrieved by a user device and/or a user group, which can be used to generate a per-data-amount billing information.

As another example, the managing unit 18 performs network operations, network administration, and/or network maintenance. Network operations includes authenticating user data allocation requests (e.g., read and/or write requests), managing creation of vaults, establishing authentication credentials for user devices, adding/deleting components (e.g., user devices, storage units, and/or computing devices with a DS client module 34) to/from the DSN 10, and/or establishing authentication credentials for the storage units 36. Network administration includes monitoring devices and/or units for failures, maintaining vault information, determining device and/or unit activation status, determining device and/or unit loading, and/or determining any other system level operation that affects the performance level of the DSN 10. Network maintenance includes facilitating replacing, upgrading, repairing, and/or expanding a device and/or unit of the DSN 10.

The integrity processing unit 20 performs rebuilding of ‘bad’ or missing encoded data slices. At a high level, the integrity processing unit 20 performs rebuilding by periodically attempting to retrieve/list encoded data slices, and/or slice names of the encoded data slices, from the DSN memory 22. For retrieved encoded slices, they are checked for errors due to data corruption, outdated version, etc. If a slice includes an error, it is flagged as a ‘bad’ slice. For encoded data slices that were not received and/or not listed, they are flagged as missing slices. Bad and/or missing slices are subsequently rebuilt using other retrieved encoded data slices that are deemed to be good slices to produce rebuilt slices. The rebuilt slices are stored in the DSN memory 22.

FIG. 2 is a schematic block diagram of an embodiment of a computing core 26 that includes a processing module 50, a memory controller 52, main memory 54, a video graphics processing unit 55, an input/output (IO) controller 56, a peripheral component interconnect (PCI) interface 58, an IO interface module 60, at least one IO device interface module 62, a read only memory (ROM) basic input output system (BIOS) 64, and one or more memory interface modules. The one or more memory interface module(s) includes one or more of a universal serial bus (USB) interface module 66, a host bus adapter (HBA) interface module 68, a network interface module 70, a flash interface module 72, a hard drive interface module 74, and a DSN interface module 76.

The DSN interface module 76 functions to mimic a conventional operating system (OS) file system interface (e.g., network file system (NFS), flash file system (FFS), disk file system (DFS), file transfer protocol (FTP), web-based distributed authoring and versioning (WebDAV), etc.) and/or a block memory interface (e.g., small computer system interface (SCSI), internet small computer system interface (iSCSI), etc.). The DSN interface module 76 and/or the network interface module 70 may function as one or more of the interface 30-33 of FIG. 1. Note that the IO device interface module 62 and/or the memory interface modules 66-76 may be collectively or individually referred to as IO ports.

FIG. 3 is a schematic block diagram of an example of dispersed storage error encoding of data. When a computing device 12 or 16 has data to store it disperse storage error encodes the data in accordance with a dispersed storage error encoding process based on dispersed storage error encoding parameters. The dispersed storage error encoding parameters include an encoding function (e.g., information dispersal algorithm, Reed-Solomon, Cauchy Reed-Solomon, systematic encoding, non-systematic encoding, on-line codes, etc.), a data segmenting protocol (e.g., data segment size, fixed, variable, etc.), and per data segment encoding values. The per data segment encoding values include a total, or pillar width, number (T) of encoded data slices per encoding of a data segment i.e., in a set of encoded data slices); a decode threshold number (D) of encoded data slices of a set of encoded data slices that are needed to recover the data segment; a read threshold number (R) of encoded data slices to indicate a number of encoded data slices per set to be read from storage for decoding of the data segment; and/or a write threshold number (W) to indicate a number of encoded data slices per set that must be accurately stored before the encoded data segment is deemed to have been properly stored. The dispersed storage error encoding parameters may further include slicing information (e.g., the number of encoded data slices that will be created for each data segment) and/or slice security information (e.g., per encoded data slice encryption, compression, integrity checksum, etc.).

In the present example, Cauchy Reed-Solomon has been selected as the encoding function (a generic example is shown in FIG. 4 and a specific example is shown in FIG. 5); the data segmenting protocol is to divide the data object into fixed sized data segments; and the per data segment encoding values include: a pillar width of 5, a decode threshold of 3, a read threshold of 4, and a write threshold of 4. In accordance with the data segmenting protocol, the computing device 12 or 16 divides the data (e.g., a file (e.g., text, video, audio, etc.), a data object, or other data arrangement) into a plurality of fixed sized data segments (e.g., 1 through Y of a fixed size in range of Kilo-bytes to Tera-bytes or more). The number of data segments created is dependent of the size of the data and the data segmenting protocol.

The computing device 12 or 16 then disperse storage error encodes a data segment using the selected encoding function (e.g., Cauchy Reed-Solomon) to produce a set of encoded data slices. FIG. 4 illustrates a generic Cauchy Reed-Solomon encoding function, which includes an encoding matrix (EM), a data matrix (DM), and a coded matrix (CM). The size of the encoding matrix (EM) is dependent on the pillar width number (T) and the decode threshold number (D) of selected per data segment encoding values. To produce the data matrix (DM), the data segment is divided into a plurality of data blocks and the data blocks are arranged into D number of rows with Z data blocks per row. Note that Z is a function of the number of data blocks created from the data segment and the decode threshold number (D). The coded matrix is produced by matrix multiplying the data matrix by the encoding matrix.

FIG. 5 illustrates a specific example of Cauchy Reed-Solomon encoding with a pillar number (T) of five and decode threshold number of three. In this example, a first data segment is divided into twelve data blocks (D1-D12). The coded matrix includes five rows of coded data blocks, where the first row of X11-X14 corresponds to a first encoded data slice (EDS 1_1), the second row of X21-X24 corresponds to a second encoded data slice (EDS 2_1), the third row of X31-X34 corresponds to a third encoded data slice (EDS 3_1), the fourth row of X41-X44 corresponds to a fourth encoded data slice (EDS 4_1), and the fifth row of X51-X54 corresponds to a fifth encoded data slice (EDS 5_1). Note that the second number of the EDS designation corresponds to the data segment number.

Returning to the discussion of FIG. 3, the computing device also creates a slice name (SN) for each encoded data slice (EDS) in the set of encoded data slices. A typical format for a slice name 60 is shown in FIG. 6. As shown, the slice name (SN) 60 includes a pillar number of the encoded data slice (e.g., one of 1-T), a data segment number (e.g., one of 1-Y), a vault identifier (ID), a data object identifier (ID), and may further include revision level information of the encoded data slices. The slice name functions as, at least part of, a DSN address for the encoded data slice for storage and retrieval from the DSN memory 22.

As a result of encoding, the computing device 12 or 16 produces a plurality of sets of encoded data slices, which are provided with their respective slice names to the storage units for storage. As shown, the first set of encoded data slices includes EDS 1_1 through EDS 5_1 and the first set of slice names includes SN 1_1 through SN 5_1 and the last set of encoded data slices includes EDS 1_Y through EDS 5_Y and the last set of slice names includes SN 1_Y through SN 5_Y.

FIG. 7 is a schematic block diagram of an example of dispersed storage error decoding of a data object that was dispersed storage error encoded and stored in the example of FIG. 4. In this example, the computing device 12 or 16 retrieves from the storage units at least the decode threshold number of encoded data slices per data segment. As a specific example, the computing device retrieves a read threshold number of encoded data slices.

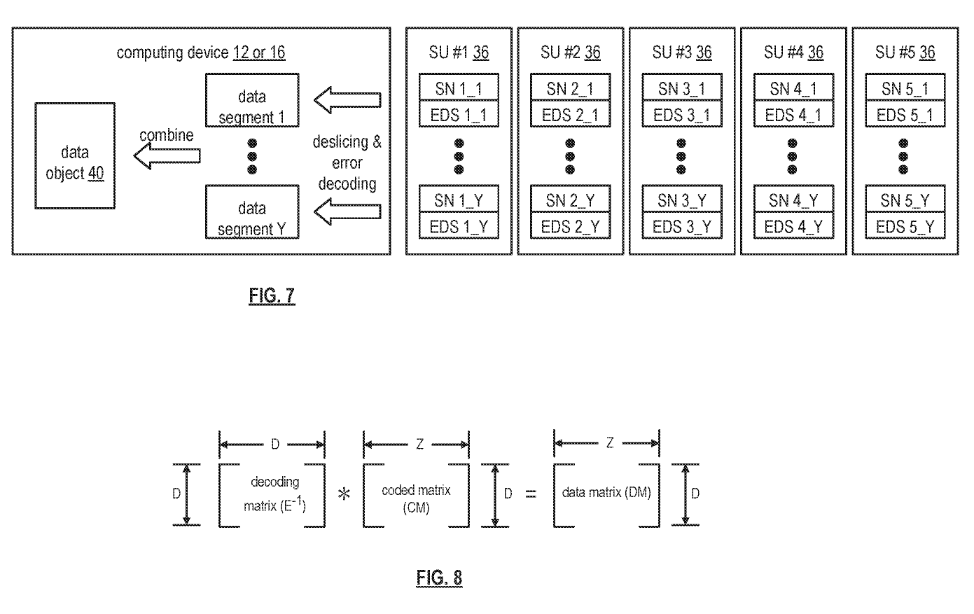

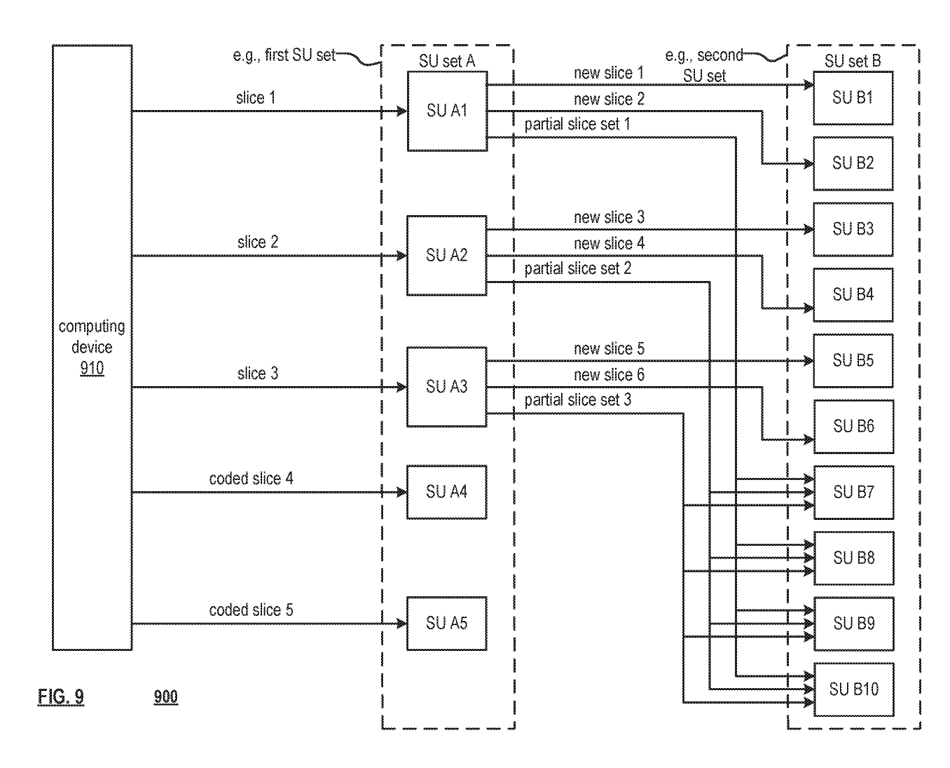

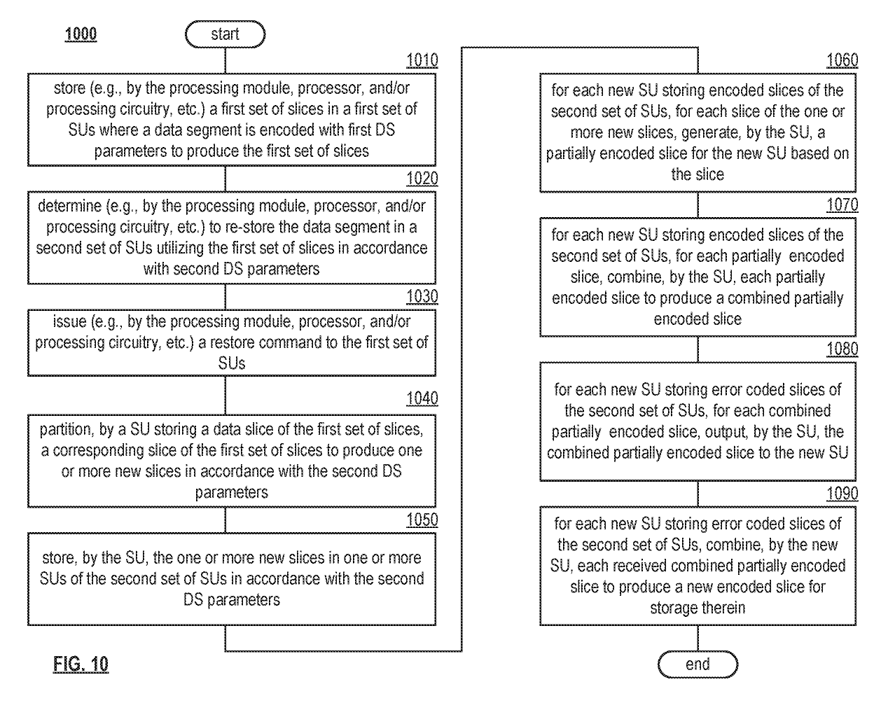

To recover a data segment from a decode threshold number of encoded data slices, the computing device uses a decoding function as shown in FIG. 8. As shown, the decoding function is essentially an inverse of the encoding function of FIG. 4. The coded matrix includes a decode threshold number of rows (e.g., three in this example) and the decoding matrix in an inversion of the encoding matrix that includes the corresponding rows of the coded matrix. For example, if the coded matrix includes rows 1, 2, and 4, the encoding matrix is reduced to rows 1, 2, and 4, and then inverted to produce the decoding matrix.

In some examples, note that dispersed or distributed storage network (DSN) memory includes one or more of a plurality of storage units (SUs) such as SUs 36 (e.g., that may alternatively be referred to a distributed storage and/or task network (DSTN) module that includes a plurality of distributed storage and/or task (DST) execution units 36 that may be located at geographically different sites (e.g., one in Chicago, one in Milwaukee, etc.). Each of the SUs (e.g., alternatively referred to as DST execution units in some examples) is operable to store dispersed error encoded data and/or to execute, in a distributed manner, one or more tasks on data. The tasks may be a simple function (e.g., a mathematical function, a logic function, an identify function, a find function, a search engine function, a replace function, etc.), a complex function (e.g., compression, human and/or computer language translation, text-to-voice conversion, voice-to-text conversion, etc.), multiple simple and/or complex functions, one or more algorithms, one or more applications, etc.

FIG. 9 is a schematic block diagram of another embodiment 900 of a distributed computing system in accordance with the present invention. This diagram includes a schematic block diagram of another embodiment of a distributed computing system that includes a computing device and at least two storage unit (SU) sets. Each SU set includes a set of SUs. Each SU may be implemented by one or more of a storage unit (SU), a storage server, a distributed computing server, a memory module, a memory device, a user device, a computing device, and a DS processing unit. The computing device may be implemented utilizing one or more of a computing device, a SU, a SU, a storage server, a distributed computing server, a user device, a DS processing unit, and a SU of the at least two SU sets. Each SU set includes a number of SUs in accordance with a pillar width number of a corresponding dispersed storage error coding function parameters. For example, a first SU set includes five SUs when a corresponding first pillar width of the first SU set is five. As another example, a second SU set includes ten SUs when a corresponding second pillar width of the second SU set is ten. Alternatively, SU sets A and B may share a common set of SUs.

The system functions to re-store data stored in the first SU set using first dispersed storage error coding parameters into the second SU set utilizing second dispersed storage error coding parameters. A data segment of data is encoded using a dispersed storage error coding function and the first dispersed storage error coding function parameters to produce a set of encoded data slices (EDSs) that are stored in the first SU set. For example, slices 1-3 are stored in a first three SUs of the first SU set and coded slices 4 and 5 are stored in a fourth and fifth SU of the first SU set when the dispersed storage error coding function parameters includes a systematic encoding matrix to produce a decode threshold number of slices (e.g., slices 1-3) that are equivalent to the data segment and two coded slices 4-5.

A processing module (e.g., of at least one of the computing device and a SU of the first and second SU sets) determines to expand the decode threshold by factor of two and the pillar width by a factor of two such that processing requirements are minimized to generate new slices. The processing module issues split commands to the first SU set where the split commands include a second encoding matrix and the second dispersed storage error coding function parameters.

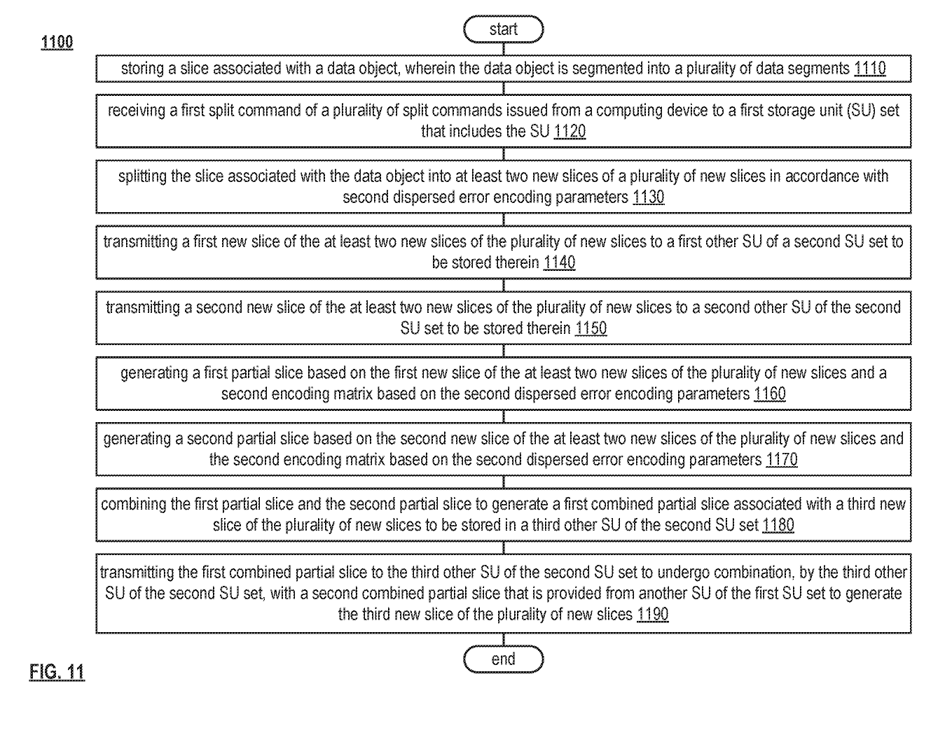

When receiving a split command, each SU associated with storage of a slice (e.g., slices 1-3 rather than coded slices 4-5) of the first SU set splits each slice into two slices and stores the two slices in two corresponding SUs of the second SU set. In addition, each SU associated with storage of the slices 1-3 generates and outputs, to each SU storing a new coded slice of the second SU set, a combined partial slice. The generating includes combining two partial slices where each partial slice is generated for the SU storing the new coded slice based on a corresponding slice and the second encoding matrix. In an example of outputting, a first SU of the first SU set outputs a partial slice set 1 to include a combined partial slice for new slice 7 based on old slices 1 and 2 (e.g., combined partial slice (7, 1, & 2)), a combined partial slice for new slice 8 based on old slices 1 and 2, a combined partial slice for new slice 9 based on old slices 1 and 2, and a combined partial slice for new slice 10 based on old slices 1 and 2. Each SU storing the new coded slice of the second SU set combines (e.g., exclusive OR) received combined partial slices to produce and store corresponding new coded slice. For example, a seventh SU of the second SU set performs an exclusive OR function on combined partial slice (7, 1, & 2), combined partial slice (7, 3, & 4), and combined partial slice (7, 5, & 6) to produce new slice 7. The method is discussed in greater detail with reference to FIG. 10.

In an example of operation and implementation, a storage unit (SU), dispersed storage (DS) unit, and/or computing device (e.g., computing device 910, SU A1) includes an interface configured to interface and communicate with a dispersed or distributed storage network (DSN), a memory that stores operational instructions, and a processing module, processor, and/or processing circuitry operably coupled to the interface and memory. The processing module, processor, and/or processing circuitry is configured to execute the operational instructions to perform various operations, functions, etc. In some examples, the processing module, processor, and/or processing circuitry, when operable within the SU, DS unit, and/or computing device, based on the operational instructions, is configured to perform various operations, functions, etc. in certain examples, the processing module, processor, and/or processing circuitry, when operable within the SU, DS unit, and/or computing device is configured to perform one or more functions that may include generation of one or more signals, processing of one or more signals, receiving of one or more signals, transmission of one or more signals, interpreting of one or more signals, etc. and/or any other operations as described herein and/or their equivalents.

In an example of operation and implementation, a SU (e.g., SU A1 if the first SU set, SU set A) is configured to store a slice associated with a data object. for example, the data object is segmented into a plurality of data segments, and a data segment of the plurality of data segments is dispersed error encoded in accordance with first dispersed error encoding parameters that includes a systematic encoding matrix to produce a decode threshold number of slices that corresponds to the data segment and a plurality of coded slices (e.g., slices 1, 2, 3 correspond to the data segment and coded slices 4 and 5 correspond to the plurality of coded slices).

Then, the SU is configured to receive a first split command of a plurality of split commands issued from a computing device (e.g., from computing device 910) to the first storage unit (SU) set (e.g., SU set A) that includes the SU (e.g., SU A1). The SU is configured to split the slice associated with the data object into at least two new slices (e.g., new slice 1 and new slice 2) of a plurality of new slices in accordance with second dispersed error encoding parameters. Then, the SU is configured to transmit (e.g., via the interface) a first new slice (e.g., new slice 1) of the at least two new slices of the plurality of new slices to a first other SU (e.g., SU B1) of a second SU set (e.g., SU set B) to be stored therein and to transmit (e.g., via the interface) a second new slice (e.g., new slice 2) of the at least two new slices of the plurality of new slices to a second other SU (e.g., SU B2) of the second SU set (e.g., SU set B) to be stored therein.

Then, the SU is configured to generate a first partial slice based on the first new slice of the at least two new slices of the plurality of new slices and a second encoding matrix based on the second dispersed error encoding parameters and also to generate a second partial slice based on the second new slice of the at least two new slices of the plurality of new slices and the second encoding matrix based on the second dispersed error encoding parameters. The SU is then configured to combine the first partial slice and the second partial slice to generate a first combined partial slice associated with a third new slice of the plurality of new slices to be stored in a third other SU (e.g., SU B7) of the second SU set (e.g., SU set B). The SU then is configured to transmit (e.g., via the interface) the first combined partial slice to the third other SU (e.g., SU B7) of the second SU set (e.g., SU set B) to undergo combination, by the third other SU (e.g., SU B7) of the second SU set (e.g., SU set B), with a second combined partial slice that is provided from another SU (e.g., SU A2) of the first SU set (e.g., SU set A) to generate the third new slice of the plurality of new slices.

Similarly, in some examples, the SU is configured to combine the first partial slice and the second partial slice to generate a third combined partial slice associated with a fourth new slice of the plurality of new slices to be stored in a fourth other SU (e.g., SU B8) of the second SU set (e.g., SU set B) and to transmit the third combined partial slice to the fourth other SU of the second SU set (e.g., SU set B) to undergo combination, by the fourth other SU (e.g., SU B8) of the second SU set (e.g., SU set B), with the second combined partial slice that is provided from the other SU (e.g., SU A2) of the first SU set (e.g., SU set A) to generate the fourth new slice of the plurality of new slices.

Also, in other examples, the SU is configured to combine the first partial slice and the second partial slice to generate a fourth combined partial slice associated with a fifth new slice of the plurality of new slices to be stored in a fifth other SU (e.g., SU B9) of the second SU set (e.g., SU set B) and transmit the fourth combined partial slice to the fifth other SU (e.g., SU B9) of the second SU set (e.g., SU set B) to undergo combination, by the fifth other SU (e.g., SU B9) of the second SU set (e.g., SU set B), with the second combined partial slice that is provided from the another SU (e.g., SU A2) of the first SU set (e.g., SU set A) and also with a fifth combined partial slice that is provided from at least one other SU (e.g., SU A3) of the first SU set (e.g., SU set A) to generate the fifth new slice of the plurality of new slices.

In some examples, the first split command (e.g., that is received from the computing device 910) includes the second dispersed error encoding parameters that include the second encoding matrix. Also, in a specific example, when the first dispersed error encoding parameters include a first pillar number that is based on the decode threshold number of slices that corresponds to the data segment and the plurality of coded slices, the second first dispersed error encoding parameters include a second pillar number that is double the first pillar number.

Note that the combination of the first combined partial slice and the second combined partial slice as performed by the third other SU (e.g., SU B7) of the second SU set (e.g., SU set B) is based on an exclusive OR operation in one implementation.

Note also that the SU (e.g., SU S1 if the first SU set, SU set A) may located at a first premises that is remotely located from a second premises of at least one other SU of the first SU set (e.g., SU set A) of the second SU set (e.g., SU set B). also, note that the computing device 910 may include another SU (e.g., SU A1, SU A2, or another SU therein) of the first SU set (e.g., SU set A), at least one other SU (e.g., SU B1, SU B2, or another SU therein) of the second SU set (e.g., SU set B), a wireless smart phone, a laptop, a tablet, a personal computers (PC), a work station, or a video game device. Also, note also that the DSN may be implemented to include or be based on any of a number of different types of communication systems including a wireless communication system, a wire lined communication system, a non-public intranet system, a public internet system, a local area network (LAN), and/or a wide area network (WAN).

With respect to dispersed error encoding of a data object, in some examples, with respect to a data object, the data object is segmented into a plurality of data segments, and a data segment of the plurality of data segments is dispersed error encoded in accordance with dispersed error encoding parameters to produce a set of encoded data slices (EDSs) that are distributedly stored in a plurality of storage units (SUs) within the DSN. In some examples, the set of EDSs is of pillar width. Also, with respect to certain implementations, note that the decode threshold number of EDSs are needed to recover the data segment, and a read threshold number of EDSs provides for reconstruction of the data segment. Also, a write threshold number of EDSs provides for a successful transfer of the set of EDSs from a first at least one location in the DSN to a second at least one location in the DSN. The set of EDSs is of pillar width and includes a pillar number of EDSs. Also, in some examples, each of the decode threshold, the read threshold, and the write threshold is less than the pillar number. Also, in some particular examples, the write threshold number is greater than or equal to the read threshold number that is greater than or equal to the decode threshold number.

FIG. 10 is a flowchart illustrating an example of re-storing data utilizing different data storage parameters in accordance with the present invention. This diagram includes a flowchart illustrating an example of re-storing data utilizing different data storage parameters. The method 1000 begins at a step 1010 where a processing module (e.g., of a computing device, a SU, and/or other device) stores a first set of slices in a first set of storage units (SUs) where a data segment is encoded with the first DS parameters to produce the first set of slices. The first DS parameters include a systematic first encoding matrix. The method 1000 continues at the step 1020 where the processing module determines to re-store the data segment in a second set of SUs utilizing the first set of slices in accordance with the second DS parameters. The determining may be based on one or more of storage reliability, storage availability, storage performance, and storage cost.

The method 1000 continues at the step 1030 where the processing module issues a re-store command to the first set of SUs. The restore command includes one or more of second DS parameters including a systematic second encoding matrix and identity of the second set of SUs. The method 1000 continues at the step 1040 where a SU storing a data slice of the first set of slices partitions a corresponding slice of the first set of slices to produce one or more new slices in accordance with the second DS parameters. For example, the SU splits the corresponding slice when a second decode threshold is greater than a first decode threshold. As another example, the SU combines with the slice from another SU when the second decode threshold is less than the first decode threshold.

The method 1000 continues in step 1050 where the SU storing the data slice of the first set of slices stores the one or more new slices in one or more SUs of the second set of SUs in accordance with the second DS parameters. For example, the SU stores a slice 1 to a first SU of the second set of SUs and stores a slice 2 to a second SU of the second set of SUs when the partitioning includes splitting the corresponding slice.

For each new SU storing encoded slices of the second set of SUs, for each slice of the one or more new slices, the method 1000 continues at the step 1060 where the SU storing the data slice of the first set of slices generates a partially encoded slice for the new SU based on the slice. For example, the SU generates a partial slice (7, 1) and partial slice (7, 2). For each new SU storing encoded slices of the second set of SUs, for each partially encoded slice, the method 1000 continues at the step 1070 where the SU storing the data slice of the first set of slices combines each partially encoded slice to produce a combined partially encoded slice. For example, the SU performs an exclusive OR function on partial slice (7, 1) and partial slice (7, 2) to produce a combined partially encoded slice (7, 1, & 2).

For each new SU storing error coded slices of the second set of SUs, for each combined partially encoded slice, the method 1000 continues at the step 1080 where the SU storing the data slice of the first set of slices outputs the combined partial encoded slice to the new SU. For each new SU storing error coded slices of the second set of SUs the method 1000 continues at the step 1090 where the new SU combines each received combined partial encoded slice to produce a new encoded slice for storage therein. For example, new SU 7 performs an exclusive OR function on partially encoded slice (7, 1, & 2), partially encoded slice (7, 3, & 4), and partially encoded slice (7, 5, & 6) to produce slice 7. Next the SU stores the new coded slice.

FIG. 11 is a diagram illustrating an embodiment of a method 1100 for execution by one or more computing devices and/or storage units (SUs) in accordance with the present invention. The method 1100 operates in step 1110 by storing a slice associated with a data object. In some examples, the data object is segmented into a plurality of data segments, and a data segment of the plurality of data segments is dispersed error encoded in accordance with first dispersed error encoding parameters that includes a systematic encoding matrix to produce a decode threshold number of slices that corresponds to the data segment and a plurality of coded slices. The method 1100 continues in step 1120 by receiving (e.g., via an interface of the SU that is configured to interface and communicate with a dispersed or distributed storage network (DSN)) a first split command of a plurality of split commands issued from a computing device to a first storage unit (SU) set that includes the SU.

The method 1100 then operates in step 1150 by splitting the slice associated with the data object into at least two new slices of a plurality of new slices in accordance with second dispersed error encoding parameters.

The method 1100 then continues in step 1140 by transmitting (e.g., via the interface) a first new slice of the at least two new slices of the plurality of new slices to a first other SU of a second SU set to be stored therein and in step 1160 by transmitting (e.g., via the interface) a second new slice of the at least two new slices of the plurality of new slices to a second other SU of the second SU set to be stored therein.

The method 1100 then operates in step 1170 by generating a first partial slice based on the first new slice of the at least two new slices of the plurality of new slices and a second encoding matrix based on the second dispersed error encoding parameters. The method 1100 then continues in step 1180 by generating a second partial slice based on the second new slice of the at least two new slices of the plurality of new slices and the second encoding matrix based on the second dispersed error encoding parameters. The method 1100 operates in step 1190 by combining the first partial slice and the second partial slice to generate a first combined partial slice associated with a third new slice of the plurality of new slices to be stored in a third other SU of the second SU set

The method 1100 operates in step 1190 by transmitting (e.g., via the interface) the first combined partial slice to the third other SU of the second SU set to undergo combination, by the third other SU of the second SU set, with a second combined partial slice that is provided from another SU of the first SU set to generate the third new slice of the plurality of new slices.

This disclosure presents, among other things, various novel solutions that can operate to transform data stored in accordance with a first information dispersal algorithm (IDA) to be stored in accordance with a second IDA. For example, in a systematic encoding algorithm (e.g., where the first K slices are composed of the data split into K pieces), it is possible to double, or half the threshold by concatenating or further splitting the slices. The coded slices, however, may need to be regenerated following this splitting operation, but during the split partial rebuilding techniques can be used to generate a single partial for the two split slices, making the calculation of the new code slices twice as efficient in terms of IO. More complex threshold shifting techniques can be produced by splitting along different boundaries and concatenating. For example, moving from a threshold of 8 to a threshold of 10 would take ⅘ of each of the 8 slices and concatenate them in a manner to produce 10 slices formed by combining different ⅘th sized pieces.

It is noted that terminologies as may be used herein such as bit stream, stream, signal sequence, etc. (or their equivalents) have been used interchangeably to describe digital information whose content corresponds to any of a number of desired types (e.g., data, video, speech, audio, etc. any of which may generally be referred to as ‘data’).

As may be used herein, the terms “substantially” and “approximately” provides an industry-accepted tolerance for its corresponding term and/or relativity between items. Such an industry-accepted tolerance ranges from less than one percent to fifty percent and corresponds to, but is not limited to, component values, integrated circuit process variations, temperature variations, rise and fall times, and/or thermal noise. Such relativity between items ranges from a difference of a few percent to magnitude differences. As may also be used herein, the term(s) “configured to”, “operably coupled to”, “coupled to”, and/or “coupling” includes direct coupling between items and/or indirect coupling between items via an intervening item (e.g., an item includes, but is not limited to, a component, an element, a circuit, and/or a module) where, for an example of indirect coupling, the intervening item does not modify the information of a signal but may adjust its current level, voltage level, and/or power level. As may further be used herein, inferred coupling (i.e., where one element is coupled to another element by inference) includes direct and indirect coupling between two items in the same manner as “coupled to”. As may even further be used herein, the term “configured to”, “operable to”, “coupled to”, or “operably coupled to” indicates that an item includes one or more of power connections, input(s), output(s), etc., to perform, when activated, one or more its corresponding functions and may further include inferred coupling to one or more other items. As may still further be used herein, the term “associated with”, includes direct and/or indirect coupling of separate items and/or one item being embedded within another item.

As may be used herein, the term “compares favorably”, indicates that a comparison between two or more items, signals, etc., provides a desired relationship. For example, when the desired relationship is that signal 1 has a greater magnitude than signal 2, a favorable comparison may be achieved when the magnitude of signal 1 is greater than that of signal 2 or when the magnitude of signal 2 is less than that of signal 1. As may be used herein, the term “compares unfavorably”, indicates that a comparison between two or more items, signals, etc., fails to provide the desired relationship.

As may also be used herein, the terms “processing module”, “processing circuit”, “processor”, and/or “processing unit” may be a single processing device or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on hard coding of the circuitry and/or operational instructions. The processing module, module, processing circuit, and/or processing unit may be, or further include, memory and/or an integrated memory element, which may be a single memory device, a plurality of memory devices, and/or embedded circuitry of another processing module, module, processing circuit, and/or processing unit. Such a memory device may be a read-only memory, random access memory, volatile memory, non-volatile memory, static memory, dynamic memory, flash memory, cache memory, and/or any device that stores digital information. Note that if the processing module, module, processing circuit, and/or processing unit includes more than one processing device, the processing devices may be centrally located (e.g., directly coupled together via a wired and/or wireless bus structure) or may be distributedly located (e.g., cloud computing via indirect coupling via a local area network and/or a wide area network). Further note that if the processing module, module, processing circuit, and/or processing unit implements one or more of its functions via a state machine, analog circuitry, digital circuitry, and/or logic circuitry, the memory and/or memory element storing the corresponding operational instructions may be embedded within, or external to, the circuitry comprising the state machine, analog circuitry, digital circuitry, and/or logic circuitry. Still further note that, the memory element may store, and the processing module, module, processing circuit, and/or processing unit executes, hard coded and/or operational instructions corresponding to at least some of the steps and/or functions illustrated in one or more of the figures. Such a memory device or memory element can be included in an article of manufacture.

One or more embodiments have been described above with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claims. Further, the boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality.

To the extent used, the flow diagram block boundaries and sequence could have been defined otherwise and still perform the certain significant functionality. Such alternate definitions of both functional building blocks and flow diagram blocks and sequences are thus within the scope and spirit of the claims. One of average skill in the art will also recognize that the functional building blocks, and other illustrative blocks, modules and components herein, can be implemented as illustrated or by discrete components, application specific integrated circuits, processors executing appropriate software and the like or any combination thereof.

In addition, a flow diagram may include a “start” and/or “continue” indication. The “start” and “continue” indications reflect that the steps presented can optionally be incorporated in or otherwise used in conjunction with other routines. In this context, “start” indicates the beginning of the first step presented and may be preceded by other activities not specifically shown. Further, the “continue” indication reflects that the steps presented may be performed multiple times and/or may be succeeded by other activities not specifically shown. Further, while a flow diagram indicates a particular ordering of steps, other orderings are likewise possible provided that the principles of causality are maintained.

The one or more embodiments are used herein to illustrate one or more aspects, one or more features, one or more concepts, and/or one or more examples. A physical embodiment of an apparatus, an article of manufacture, a machine, and/or of a process may include one or more of the aspects, features, concepts, examples, etc. described with reference to one or more of the embodiments discussed herein. Further, from figure to figure, the embodiments may incorporate the same or similarly named functions, steps, modules, etc. that may use the same or different reference numbers and, as such, the functions, steps, modules, etc. may be the same or similar functions, steps, modules, etc. or different ones.

Unless specifically stated to the contra, signals to, from, and/or between elements in a figure of any of the figures presented herein may be analog or digital, continuous time or discrete time, and single-ended or differential. For instance, if a signal path is shown as a single-ended path, it also represents a differential signal path. Similarly, if a signal path is shown as a differential path, it also represents a single-ended signal path. While one or more particular architectures are described herein, other architectures can likewise be implemented that use one or more data buses not expressly shown, direct connectivity between elements, and/or indirect coupling between other elements as recognized by one of average skill in the art.

The term “module” is used in the description of one or more of the embodiments. A module implements one or more functions via a device such as a processor or other processing device or other hardware that may include or operate in association with a memory that stores operational instructions. A module may operate independently and/or in conjunction with software and/or firmware. As also used herein, a module may contain one or more sub-modules, each of which may be one or more modules.

As may further be used herein, a computer readable memory includes one or more memory elements. A memory element may be a separate memory device, multiple memory devices, or a set of memory locations within a memory device. Such a memory device may be a read-only memory, random access memory, volatile memory, non-volatile memory, static memory, dynamic memory, flash memory, cache memory, and/or any device that stores digital information. The memory device may be in a form a solid state memory, a hard drive memory, cloud memory, thumb drive, server memory, computing device memory, and/or other physical medium for storing digital information.

While particular combinations of various functions and features of the one or more embodiments have been expressly described herein, other combinations of these features and functions are likewise possible. The present disclosure is not limited by the particular examples disclosed herein and expressly incorporates these other combinations.

What is claimed is:

1. A storage unit (SU) comprising:
an interface configured to interface and communicate with a dispersed or distributed storage network (DSN);
memory that stores operational instructions; and
processing circuitry operably coupled to the interface and to the memory, wherein the processing circuitry is configured to execute the operational instructions to:
store a slice associated with a data object, wherein the data object is segmented into a plurality of data segments, wherein a data segment of the plurality of data segments is dispersed error encoded in accordance with first dispersed error encoding parameters that includes a systematic encoding matrix to produce a decode threshold number of slices that corresponds to the data segment and a plurality of coded slices;
receive a first split command of a plurality of split commands issued from a computing device to a first storage unit (SU) set that includes the SU;
split the slice associated with the data object into at least two new slices of a plurality of new slices in accordance with second dispersed error encoding parameters;
transmit a first new slice of the at least two new slices of the plurality of new slices to a first other SU of a second SU set to be stored therein;
transmit a second new slice of the at least two new slices of the plurality of new slices to a second other SU of the second SU set to be stored therein;
generate a first partial slice based on the first new slice of the at least two new slices of the plurality of new slices and a second encoding matrix based on the second dispersed error encoding parameters;
generate a second partial slice based on the second new slice of the at least two new slices of the plurality of new slices and the second encoding matrix based on the second dispersed error encoding parameters;
combine the first partial slice and the second partial slice to generate a first combined partial slice associated with a third new slice of the plurality of new slices to be stored in a third other SU of the second SU set; and
transmit the first combined partial slice to the third other SU of the second SU set to undergo combination, by the third other SU of the second SU set, with a second combined partial slice that is provided from another SU of the first SU set to generate the third new slice of the plurality of new slices.

2. The SU of claim 1, wherein the processing circuitry is further configured to execute the operational instructions to:
combine the first partial slice and the second partial slice to generate a third combined partial slice associated with a fourth new slice of the plurality of new slices to be stored in a fourth other SU of the second SU set; and
transmit the third combined partial slice to the fourth other SU of the second SU set to undergo combination, by the fourth other SU of the second SU set, with the second combined partial slice that is provided from the another SU of the first SU set to generate the fourth new slice of the plurality of new slices.

3. The SU of claim 1, wherein the processing circuitry is further configured to execute the operational instructions to:
combine the first partial slice and the second partial slice to generate a fourth combined partial slice associated with a fifth new slice of the plurality of new slices to be stored in a fifth other SU of the second SU set; and
transmit the fourth combined partial slice to the fifth other SU of the second SU set to undergo combination, by the fifth other SU of the second SU set, with the second combined partial slice that is provided from the another SU of the first SU set and also with a fifth combined partial slice that is provided from at least one other SU of the first SU set to generate the fifth new slice of the plurality of new slices.

4. The SU of claim 1, wherein:
the first split command includes the second dispersed error encoding parameters that include the second encoding matrix;
the first dispersed error encoding parameters include a first pillar number that is based on the decode threshold number of slices that corresponds to the data segment and the plurality of coded slices; and
the second first dispersed error encoding parameters include a second pillar number that is double the first pillar number.

5. The SU of claim 1, the combination of the first combined partial slice and the second combined partial slice as performed by the third other SU of the second SU set is based on an exclusive OR operation.

6. The SU of claim 1, wherein the SU is located at a first premises that is remotely located from a second premises of at least one other SU of the first SU set of the second SU set.

7. The SU of claim 1, wherein the computing device includes the another SU of the first SU set, at least one other SU of the second SU set, a wireless smart phone, a laptop, a tablet, a personal computers (PC), a work station, or a video game device.

8. The SU of claim 1, wherein the DSN includes at least one of a wireless communication system, a wire lined communication system, a non-public intranet system, a public internet system, a local area network (LAN), or a wide area network (WAN).

9. A storage unit (SU) comprising:
an interface configured to interface and communicate with a dispersed or distributed storage network (DSN);
memory that stores operational instructions; and
store a slice associated with a data object, wherein the data object is segmented into a plurality of data segments, wherein a data segment of the plurality of data segments is dispersed error encoded in accordance with first dispersed error encoding parameters that includes a systematic encoding matrix to produce a decode threshold number of slices that corresponds to the data segment and a plurality of coded slices;
receive a first split command of a plurality of split commands issued from a computing device to a first storage unit (SU) set that includes the SU;
split the slice associated with the data object into at least two new slices of a plurality of new slices in accordance with second dispersed error encoding parameters;
transmit a first new slice of the at least two new slices of the plurality of new slices to a first other SU of a second SU set to be stored therein;
transmit a second new slice of the at least two new slices of the plurality of new slices to a second other SU of the second SU set to be stored therein;
generate a first partial slice based on the first new slice of the at least two new slices of the plurality of new slices and a second encoding matrix based on the second dispersed error encoding parameters;
generate a second partial slice based on the second new slice of the at least two new slices of the plurality of new slices and the second encoding matrix based on the second dispersed error encoding parameters;
combine the first partial slice and the second partial slice to generate a first combined partial slice associated with a third new slice of the plurality of new slices to be stored in a third other SU of the second SU set;
transmit the first combined partial slice to the third other SU of the second SU set to undergo combination, by the third other SU of the second SU set, with a second combined partial slice that is provided from another SU of the first SU set to generate the third new slice of the plurality of new slices;
combine the first partial slice and the second partial slice to generate a third combined partial slice associated with a fourth new slice of the plurality of new slices to be stored in a fourth other SU of the second SU set; and
transmit the third combined partial slice to the fourth other SU of the second SU set to undergo combination based on an exclusive OR operation, by the fourth other SU of the second SU set, with the second combined partial slice that is provided from the another SU of the first SU set to generate the fourth new slice of the plurality of new slices.

10. The SU of claim 9, wherein the processing circuitry is further configured to execute the operational instructions to:
combine the first partial slice and the second partial slice to generate a fourth combined partial slice associated with a fifth new slice of the plurality of new slices to be stored in a fifth other SU of the second SU set; and
transmit the fourth combined partial slice to the fifth other SU of the second SU set to undergo combination, by the fifth other SU of the second SU set, with the second combined partial slice that is provided from the another SU of the first SU set and also with a fifth combined partial slice that is provided from at least one other SU of the first SU set to generate the fifth new slice of the plurality of new slices.

11. The SU of claim 9, wherein:
the first split command includes the second dispersed error encoding parameters that include the second encoding matrix;
the first dispersed error encoding parameters include a first pillar number that is based on the decode threshold number of slices that corresponds to the data segment and the plurality of coded slices; and
the second first dispersed error encoding parameters include a second pillar number that is double the first pillar number.

12. The SU of claim 9, wherein the computing device includes the another SU of the first SU set, at least one other SU of the second SU set, a wireless smart phone, a laptop, a tablet, a personal computers (PC), a work station, or a video game device.

13. The SU of claim 9, wherein the DSN includes at least one of a wireless communication system, a wire lined communication system, a non-public intranet system, a public internet system, a local area network (LAN), or a wide area network (WAN).

14. A method for execution by a storage unit (SU), the method comprising:
storing a slice associated with a data object, wherein the data object is segmented into a plurality of data segments, wherein a data segment of the plurality of data segments is dispersed error encoded in accordance with first dispersed error encoding parameters that includes a systematic encoding matrix to produce a decode threshold number of slices that corresponds to the data segment and a plurality of coded slices;
receiving, via an interface of the SU that is configured to interface and communicate with a dispersed or distributed storage network (DSN), a first split command of a plurality of split commands issued from a computing device to a first storage unit (SU) set that includes the SU;
splitting the slice associated with the data object into at least two new slices of a plurality of new slices in accordance with second dispersed error encoding parameters;
transmitting, via the interface, a first new slice of the at least two new slices of the plurality of new slices to a first other SU of a second SU set to be stored therein;
transmitting, via the interface, a second new slice of the at least two new slices of the plurality of new slices to a second other SU of the second SU set to be stored therein;
generating a first partial slice based on the first new slice of the at least two new slices of the plurality of new slices and a second encoding matrix based on the second dispersed error encoding parameters;
generating a second partial slice based on the second new slice of the at least two new slices of the plurality of new slices and the second encoding matrix based on the second dispersed error encoding parameters;
combining the first partial slice and the second partial slice to generate a first combined partial slice associated with a third new slice of the plurality of new slices to be stored in a third other SU of the second SU set; and
transmitting, via the interface, the first combined partial slice to the third other SU of the second SU set to undergo combination, by the third other SU of the second SU set, with a second combined partial slice that is provided from another SU of the first SU set to generate the third new slice of the plurality of new slices.

15. The method of claim 14 further comprising:
combining the first partial slice and the second partial slice to generate a third combined partial slice associated with a fourth new slice of the plurality of new slices to be stored in a fourth other SU of the second SU set; and
transmitting, via the interface, the third combined partial slice to the fourth other SU of the second SU set to undergo combination, by the fourth other SU of the second SU set, with the second combined partial slice that is provided from the another SU of the first SU set to generate the fourth new slice of the plurality of new slices.

16. The method of claim 14 further comprising:
combining the first partial slice and the second partial slice to generate a fourth combined partial slice associated with a fifth new slice of the plurality of new slices to be stored in a fifth other SU of the second SU set; and
transmitting, via the interface, the fourth combined partial slice to the fifth other SU of the second SU set to undergo combination, by the fifth other SU of the second SU set, with the second combined partial slice that is provided from the another SU of the first SU set and also with a fifth combined partial slice that is provided from at least one other SU of the first SU set to generate the fifth new slice of the plurality of new slices.

17. The method of claim 14 further comprising:
combining the first partial slice and the second partial slice to generate a fourth combined partial slice associated with a fifth new slice of the plurality of new slices to be stored in a fifth other SU of the second SU set; and
transmitting, via the interface, the fourth combined partial slice to the fifth other SU of the second SU set to undergo combination, by the fifth other SU of the second SU set, with the second combined partial slice that is provided from the another SU of the first SU set and also with a fifth combined partial slice that is provided from at least one other SU of the first SU set to generate the fifth new slice of the plurality of new slices.

18. The method of claim 14, wherein:
the first split command includes the second dispersed error encoding parameters that include the second encoding matrix;
the first dispersed error encoding parameters include a first pillar number that is based on the decode threshold number of slices that corresponds to the data segment and the plurality of coded slices; and
the second first dispersed error encoding parameters include a second pillar number that is double the first pillar number.

19. The method of claim 14, wherein the computing device includes the another SU of the first SU set, at least one other SU of the second SU set, a wireless smart phone, a laptop, a tablet, a personal computers (PC), a work station, or a video game device.

20. The method of claim 14, wherein the DSN includes at least one of a wireless communication system, a wire lined communication system, a non-public intranet system, a public internet system, a local area network (LAN), or a wide area network (WAN).
